(19) United States
(12) Patent Application Publication
(10) Pub. No.: US 2025/0089422 A1
(43) Pub. Date: Mar. 13, 2025

(54) DISPLAY DEVICE AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventors: Mingqiang WANG, Beijing (CN); Zheng BAO, Beijing (CN); Dexing HE, Beijing (CN); Jiaxiang ZHANG, Beijing (CN); Chang WANG, Beijing (CN); Hongjin HU, Beijing (CN); Yuan FANG, Beijing (CN); Bin ZHANG, Beijing (CN); Seungyong OH, Beijing (CN)

(21) Appl. No.: 18/577,248

(22) PCT Filed: May 26, 2023
(86) PCT No.: PCT/CN2023/096551

§ 371 Date: Jan. 6, 2024

(30) Foreign Application Priority Data
May 30, 2022 (CN) 202210602554.3

(51) Int. Cl. H01L 33/62; H01L 25/16; H04B 5/43

(52) U.S. Cl. CPC H10H 20/857; H01L 25/167; H04B 5/43

(57) ABSTRACT

Provided is a display device. The display device includes a display panel and a circuit board. The display panel includes a display region and a non-display region. A first wiring is distributed in the non-display region. A second wiring is distributed in the circuit board. The circuit board is bonded to the non-display region, and the second wiring is connected to the first wiring to form a near-field communication antenna.

### CROSS-REFERENCE TO RELATED APPLICATION

This application is a U.S. national stage of international application No. PCT/CN2023/096551, field on May 26, 2023, which claims priority to Chinese Patent Application No. 202210602554.3, filed on May 30, 2022, and entitled “DISPLAY MODULE AND DISPLAY APPARATUS,” the contents of which are herein incorporated by reference in their entities.

### TECHNICAL FIELD

The present disclosure relates to the field of display technologies, and in particular, relates to a display device and a display apparatus.

### BACKGROUND

This part is intended to provide background or context for the embodiments in the claims. The descriptions herein are not recognized as the related art by virtue of their inclusion in this part.

### SUMMARY

According to some embodiments of the present disclosure, a display device is provided. The display device includes a display panel and a circuit board, wherein the display panel includes a display region and a non-display region; wherein a first wiring is distributed in the non-display region; a second wiring is distributed in the circuit board; and the circuit board is bonded to the non-display region, and the second wiring is connected to the first wiring to form a near-field communication antenna.

In some embodiments, the non-display region includes a non-bonding region surrounding the display region and a bonding region disposed at an edge, distal from the display region, of the non-bonding region, wherein the first wiring is disposed at least in the bonding region.

In some embodiments, the bonding region includes a first pad region provided with a plurality of first pads, wherein the first pad region is disposed at an edge, distal from the non-bonding region, of the bonding region, the first wiring is outside the first pad region, and at least one end of the first wiring is connected to the first pad; the circuit board includes a second pad region provided with a plurality of second pads, wherein the second pad region is disposed at an edge of the circuit board, the second wiring is outside the second pad region, and at least one end of the second wiring is connected to the second pad; and the plurality of first pads are bonded to the plurality of second pads.

In some embodiments, the plurality of first pads are provided along an edge of the bonding region, and the first wiring is connected to an outermost first pad of the plurality of first pads.

In some embodiments, the plurality of second pads are provided along an edge of the circuit board, and the second wiring is connected to an outermost second pad of the plurality of second pads.

In some embodiments, the second wirings are provided along an edge of the circuit board.

In some embodiments, the display device further includes a driver chip, wherein the driver chip is bonded to the bonding region and between the first pad region and the non-bonding region, and at least one of the first wirings travels through a gap region between the first pad region and the driver chip.

In some embodiments, the first wirings are all disposed in a same layer and are all disposed in the gap region.

In some embodiments, at least one of the first wirings includes a first segment and a second segment, wherein the first segment is disposed in the gap region, the second segment is disposed in the non-bonding region and surrounds the display region, and the first segment and the second segment are disposed in a same layer and connected to each other by a first jumper.

In some embodiments, the non-display region further includes a bendable region, wherein the bendable region is disposed between the non-bonding region and the bonding region.

In some embodiments, the circuit board is disposed on a back side of the display panel, the circuit board is provided with a plurality of wiring layers, and the second wirings are all disposed in a bottom wiring layer of the circuit board, wherein the bottom wiring layer is a wiring layer, most proximal to the display panel, of the circuit board.

In some embodiments, the circuit board is disposed on a back side of the display panel, the circuit board is provided with a plurality of wiring layers, at least two second wirings are provided, and each of the second wirings is at least partially disposed in a bottom wiring layer of the circuit board, wherein the bottom wiring layer is a wiring layer, most proximal to the display panel, of the circuit board, and at least one of the second wirings spans over the other of the second wirings by a second jumper.

In some embodiments, the display device further includes a plurality of first wirings and a plurality of second wirings, wherein the plurality of first wirings and the plurality of second wirings are connected to form an antenna coil, and one end of one of the plurality of second wirings and one end of another of plurality of second wirings are lead ends of the antenna coil.

In some embodiments, the circuit board further includes a connector, wherein the connector is disposed on an inner side of the antenna coil, and the lead end is connected to the connector.

In some embodiments, the circuit board includes at least two layers of wirings, at least one of the two lead ends of the antenna coil extends to the inner side of the antenna coil by a second jumper, and portions of the second wirings, except for the second jumper, are disposed in a same layer.

In some embodiments, the display device includes a display panel and a circuit board. The display panel includes a display region and a non-display region surrounding the display region. The non-display region includes a first pad region and at least one first wiring, and a plurality of first pads are within the first pad region. The circuit board includes a second pad region and at least two second wirings, and a plurality of second pads are within the second pad region. Each end of the first wiring is connected to one of the first pads, and at least one end of the second wiring is connected the second pad. The at least two second wirings are both open loop structures and are both disposed in an edge region of the circuit board. A wiring region where the at least two second wirings are disposed has an opening toward the second pad region. The second pad is bonded to the first pad, such that the at least one first wiring and the at least two second wirings are connected to form a near field communication antenna.

In some embodiments, the display panel further includes a third pad region, and a plurality of third pads are within the third pad region. The display device further includes a driver chip. The driver chip is bonded to the third pad, and at least one of the first wirings travels through a gap region between the first pad region and the third pad region.

In some embodiments, the first wirings are disposed in a same layer, and a minimum encircling rectangle of any of the first wirings is disposed on a side, toward the first pad region, of the third pad region.

In some embodiments, the display panel further includes a substrate, and a transistor and a light-shielding layer that are disposed on the substrate, wherein the light-shielding layer is opposite to an active layer of the transistor and between the active layer and the substrate, and the first wiring and the light-shielding layer are disposed in a same layer.

In some embodiments, at least one of the first wirings includes: a first segment traveling through the gap region and a second segment surrounding the display region of the display panel, wherein the first segment and the second segment are disposed in a same layer and connected in series by a first jumper.

In some embodiments, the display panel further includes a substrate, and a transistor and a light-shielding layer that are disposed on the substrate, wherein the light-shielding layer is opposite to an active layer of the transistor and between the active layer and the substrate, and the first segment and the second segment are disposed in a same layer as the light-shielding layer.

In some embodiments, the circuit board includes at least two layers of wirings and a connector. The at least two second wirings are disposed in an edge region of the circuit board. The connector is disposed on an inner side of a minimum encircling rectangle defined by the at least two second wirings. The at least one first wiring and the at least two second wirings are connected to form an antenna coil of multiple turns, wherein one end of each of the two second wirings is served as a lead end, and the lead end is connected to the connector. At least one of the second wirings spans over other second wirings by a jumper, and the at least two second wirings are disposed in a same layer except for the jumper.

In some embodiments, the display panel is a flexible panel. In the case that the display panel is in a flat state, the bendable region of the display panel is disposed on a side, distal from the first pad region, of the third pad region.

In some embodiments, the circuit board is provided with a plurality of wiring layers. In the case that the display panel is in a bending state, the circuit board is fixed to the back side of the display panel. A wiring layer, most proximal to the display panel, of the circuit board is a bottom wiring layer of the circuit board, and the second wirings are all disposed in the bottom wiring layer of the circuit board.

In some embodiments, the circuit board is provided with a plurality of wiring layers. In the case that the display panel is in a bending state, the circuit board is fixed to the back side of the display panel. A wiring layer, most proximal to the display panel, of the circuit board is a bottom wiring layer of the circuit board. At least one of the second wirings spans over other second wirings by a second jumper, and the at least two second wirings are all disposed in the bottom wiring layer of the circuit board except for the second jumper.

In some embodiments, the circuit board includes at least two layers of wirings and a connector. The connector is disposed on an inner side of a wiring region where the at least two second wirings are disposed. The at least one first wiring and the at least two second wirings are connected to form an antenna coil of multiple turns, wherein one end of each of the two second wirings is served as a lead end, and the lead end is connected to the connector. At least one of the second wirings spans over other second wirings by a second jumper, and the at least two second wirings are disposed in a same layer except for the second jumper.

In some embodiments, the display panel includes a light-emitting diode display panel.

According to some embodiments of the present disclosure, a display apparatus is provided. The display apparatus includes the display device as described above.

### BRIEF DESCRIPTION OF DRAWINGS

FIG. 1 is a top view of a display panel and a driver chip that are in an assembled state according to some embodiments of the present disclosure;

FIG. 2 is a top view of a circuit board according to some embodiments of the present disclosure;

FIG. 3 is a schematic structural diagram of a display device in which the circuit board illustrated in FIG. 2 and the display panel illustrated in FIG. 1 are involved, wherein the display panel is in a flat state;

FIG. 4 is a schematic diagram of a layer structure of different regions of the display device illustrated in FIG. 3;

FIG. 5 is a schematic structural diagram of a display device according to some embodiments of the present disclosure, wherein the display panel is in a bending state;

FIG. 6 is a schematic structural diagram of a display device of some embodiments of the present disclosure, wherein the display panel is in a flat state; and

FIG. 7 is a schematic diagram of a layer structure of different regions of the display device illustrated in FIG. 6.

Reference numerals and denotations thereof: 1—Display panel; 11—Display region; 12—Bendable region; 13—First pad; 14—First wiring; 2—Driver chip; 3—Circuit board; 31—Second pad; 32—Second wiring; 33—Connector; 14c—First jumper; 34—Second jumper; 4—Ferrite layer; 5—Polarizer; 6—Optical adhesive; 7—Cover; 14a—First segment; 14b—Second segment; PI1—First substrate; Barrier1—First shielding layer; PI2—Second substrate; BSM—Light-shielding layer; Barrier2—Second shielding layer; Buffer—Buffer Layer; P—Si—Active layer; GI1, GI2, ILD—Insulation layer; Gate1, Gate2, SD—Metal layer; PLN—Planarization layer; Cathode—Cathode layer; CVD1, CVD2—Insulation layer; IJP—Inkjet printing layer; Metal1, Metal2—Metal layer; Insulation—Insulation layer; OC—Organic insulation layer.

### DETAILED DESCRIPTION

The present disclosure is described in further detail with reference to the accompanying drawings.

Near-field communication (NFC) is a set of communication protocols that enable contactless identification and interconnection using near-field magnetic field communication. The NFC enables near-field wireless communication between mobile devices and consumer electronics due to the features of a close transmission distance, low energy consumption, and signals that are less susceptible to interference.

NFC has been commonly used in electronic devices for data exchange. For implementation of NFC, a communication antenna needs to be mounted on the device for transmitting and receiving electromagnetic wave signals.

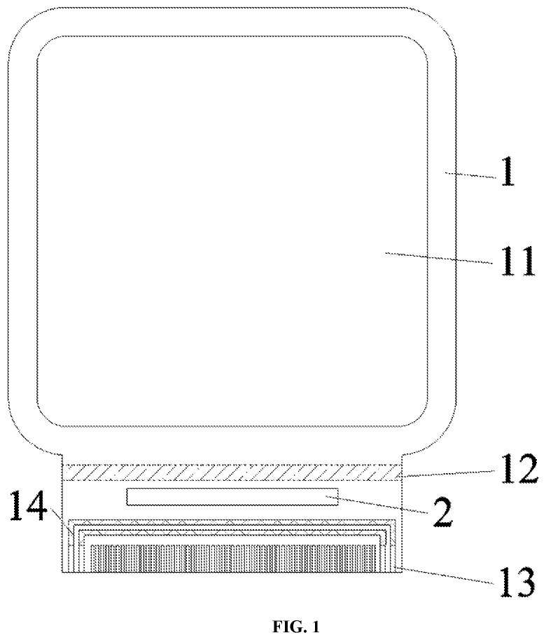

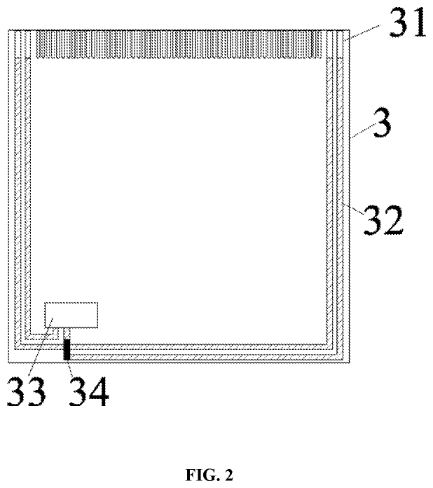

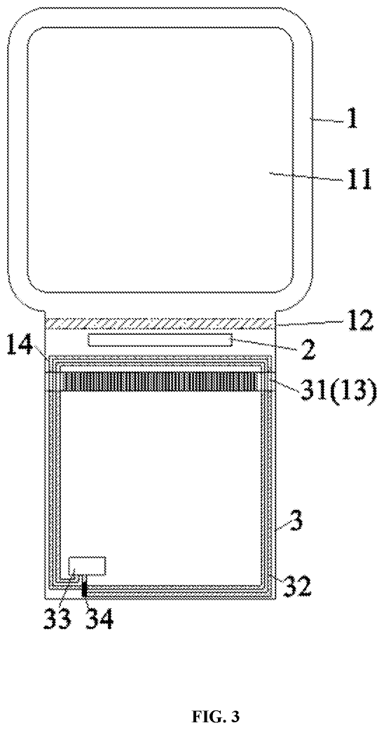

FIG. 1 is a top view of a display panel and a driver chip that are in an assembled state according to some embodiments of the present disclosure. FIG. 2 is a top view of a circuit board according to some embodiments of the present disclosure. FIG. 3 is a schematic structural diagram of a display device in which the circuit board illustrated in FIG. 2 and the display panel illustrated in FIG. 1 are involved, wherein the display panel is in a flat state.

Referring to FIG. 1 to FIG. 3, some embodiments of the present disclosure provide a display device. The display device includes a display panel 1 and a circuit board 3. The display panel 1 includes a display region 11 and a non-display region surrounding the display region 11.

A first wiring 14 is distributed in the non-display region and a second wiring 32 is distributed in the circuit board 3. The circuit board 3 is bonded to the non-display region. The second wiring 32 is connected to the first wiring 14 to form a near-field communication antenna.

In some practices, most of the electronic devices utilizing the NFC communication technology are designed to externalize a separate NFC communication module on a main board of the electronic device, which needs to occupy a large space, and thus it is not conducive to the thin and light design of the device. In the embodiments of the present disclosure, the connection between the first wiring 14 and the second wiring 32 is achieved by bonding the circuit board to the display panel, such that the NFC antenna is integrated into the display device.

The non-display region includes a non-bonding region surrounding the display region 11 and a bonding region that is disposed at an edge, distal from the display region 11, of the non-bonding region. The first wiring 14 is disposed at least in the bonding region. As illustrated in FIG. 1, the non-bonding region is a box-shaped region surrounding the display region 11 in the non-display region illustrated in FIG. 1, and the bonding region is a rectangular region attached to an outside of the box-shaped region in FIG. 1.

The bonding region includes a first pad region in which a plurality of first pads 13 are distributed. The first pad region is disposed at an edge, distal from the non-bonding region, of the bonding region, the first wiring 14 is outside of the first pad region, and at least one end of the first wiring 14 is connected to the first pad 13.

The circuit board 3 includes a second pad region in which a plurality of second pads 31 are distributed. The second pad region is disposed at an edge of the circuit board 3, the second wiring 32 is outside of the second pad region, and at least one end of the second wiring 32 is connected to the second pad 31. The plurality of first pads 13 are bonded to the plurality of second pads 31. By bonding the plurality of first pads 13 with the plurality of second pads 31, the circuit board 3 is connected to the display panel 1 at the same time that the first wiring 14 is connected to the second wiring 32.

In some embodiments, the non-display region includes the first pad region and at least one first wiring 14, with the plurality of first pads 13 within the first pad region. The circuit board 3 includes a second pad region and at least two second wirings 32, with the plurality of second pads 31 within the second pad region. Each end of the first wiring 14 is connected to one of the first pads 13, and at least one end of the second wiring 32 is connected to the second pad 31. The at least two second wirings 32 are both open loop structures and are both disposed in an edge region of the circuit board 3. A wiring region in which the at least two second wirings 32 are disposed has an opening towards the second pad region. The second pad 31 is bonded to the first pad 13 such that the at least one first wiring 14 and the at least two second wirings 32 are connected to form the near-field communication antenna

In these embodiments, the connection of the first wiring 14 and the second wiring 32 is achieved by bonding the circuit board to the display panel, such that the near-field communication antenna is integrated into the display device.

As illustrated in FIG. 1, the plurality of first pads 13 are provided along an edge of the bonding region, and the first wiring 14 is connected to an outermost first pad 13 of the plurality of first pads 13, which facilitates the increasing of an area enclosed by an antenna coil formed by connecting the first wiring 14 to the second wiring 32.

Similarly, as illustrated in FIG. 2, the plurality of second pads 31 are provided along an edge of the circuit board 3, and the second wiring 32 is connected to an outermost second pad 31 of the plurality of second pads 31, which further increases the area enclosed by the antenna coil formed by connecting the first wiring 14 to the second wiring 32.

In some embodiments, the plurality of first wirings 14 and the plurality of second wirings 32 are connected to form the antenna coil, with an end of one second wiring 32 of the plurality of second wirings 32 and an end of another second wiring 32 of the plurality of second wirings 32 being lead ends of the antenna coil.

The second wirings 32 are provided along an edge of the circuit board 3. A central region of the circuit board 3 typically includes a high-speed signal wiring and a power supply wiring, and the second wiring 32 is disposed in the edge region of the circuit board 3. In this way, the second wiring 32 is structurally non-interfering with the high-speed signal wiring and the power supply wiring, and also the second wiring 32 is non-interfering with the high-speed signal wiring and the power supply wiring in terms of electrical properties.

The second wiring 32 is disposed in the edge region of the circuit board 3, which allows the area enclosed by the near-field communication antenna to be sufficiently large, such that the strength of magnetic field signals excited by the near-field communication antenna is sufficiently large.

In some embodiments, a distance between an outer boundary of the wiring region where the second wiring 32 is disposed and a boundary of the circuit board 3 is 0.2 mm, and a distance between an inner boundary of the wiring region where the second wiring 32 is disposed and the boundary of the circuit board 3 ranges from 2.5 mm to 4 mm.

In some embodiments, the circuit board 3 is a flexible circuit board or a rigid circuit board.

In some embodiments, referring to FIG. 3, the bonding region further includes a third pad region (a region of the display panel covered by the driver chip 2 in FIG. 1 and FIG. 3), and a plurality of third pads (not illustrated) are provided within the third pad region. The display device further includes a driver chip 2, and the driver chip 2 is bonded to the third pad. At least one first wiring 14 travels through a gap region between the first pad region and the third pad region. That is, the at least one first wiring 14 travels through a gap region between the first pad region and the driver chip 2.

In some embodiments, a gap, greater than 0.8 mm, is present between the driver chip 2 and the first pad region. In some specific embodiments, a gap of 1.83 mm is present between the driver chip 2 and the first pad region. such a wide gap region is sufficient for arranging at least two first wirings 14.

In these embodiments, the gap region in the display panel between the first pad region and the third pad region is fully utilized for wiring the near-field communication antenna.

In some embodiments, referring to FIG. 3, the first wirings 14 are disposed in the same layer and are all disposed in the gap region described above. A minimum encircling rectangle of any of the first wirings 14 is disposed on a side, toward the first pad region, of the third pad region.

The minimum encircling rectangle of a wiring refers to a rectangular contour with the minimum area encircling the wiring.

The term that the two structures are disposed in the same layer herein indicates that both structures are formed by the same material layer, but does not limit whether the heights of the two are equal.

In these embodiments, each turn of the wirings of the near-field communication antenna travels through the edge region of the circuit board 3 and the gap region between the first pad region and the third pad region.

In some embodiments of the present disclosure, a light exiting side of the display panel is referred to as its front side, and the non-light exiting side of the display panel is referred to as its back side.

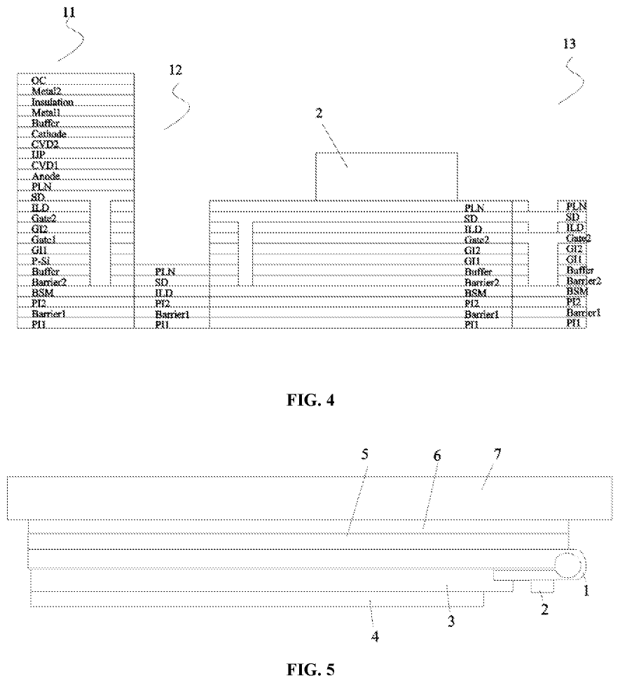

In some embodiments, referring to FIG. 4, the display panel further includes a substrate, and a top-gate transistor and a light-shielding layer BSM that are disposed on the substrate. The light-shielding layer BSM is disposed opposite to an active layer P—Si of the top-gate transistor and between the active layer P—Si and the substrate. The first wiring 14 and the light-shielding layer BSM are disposed in the same layer.

The light-shielding layer BSM is a wiring layer most proximal to the substrate. There are relatively few connections between the light-shielding layer BSM and other wiring layers, and there is more than enough wiring space in the wiring layer where the light-shielding layer BSM is disposed for the first wiring 14. Moreover, by disposing the first wiring 14 in the wiring layer where the light-shielding layer BSM is disposed, the near-field communication antenna has less impact on the wirings related to display or touch.

Specifically, referring to FIG. 4, along a direction pointing from the back side of the display panel to the front side thereof, the display region 11 of the display panel includes a first substrate PI1, a shielding layer Barrier1, a second substrate PI2, a light-shielding layer BSM, a second shielding layer Barrier2, a buffer layer Buffer, an active layer P—Si, an insulation layer GI1, a metal layer Gate1, an insulation layer GI2, a metal layer Gate2, an insulation layer ILD, a metal layer SD, a planarization layer PLN, an anode layer Anode, an insulation layer CVD1, an inkjet printing layer IJP, an insulation layer CVD2, and a cathode layer Cathode, which are successively stacked. These structures are configured to implement the display function. The display panel further includes a buffer layer Buffer, a metal layer Metal1, an insulation layer Insulation, a metal layer Metal2, and an organic insulation layer OC, which are configured to implement the touch function.

Materials, structures, and functions of the layer structures are not limited herein and may be set by those skilled in the art in accordance with some practices. In some embodiments, a gate electrode of the top-gate transistor is disposed in the metal layer Gate1, and a source-drain electrode thereof is disposed in the metal layer SD. As another example, in some embodiments, the active layer of the top-gate transistor is made of polycrystalline silicon, amorphous silicon, or an oxide semiconductor. As another example, in some embodiments, the first substrate PI1, the shielding layer Barrier1, and the second substrate PI2 form a substrate of a composite structure.

The non-display region further includes a bendable region 12, wherein the bendable region 12 is disposed between the non-bonding region and the bonding region. Along the direction pointing from the back side of the display panel to the front side thereof, the bendable region 12 of the display panel includes the first substrate PI1, the first shielding layer Barrier1, the second substrate PI2, the insulation layer ILD, the metal layer SD, and the planarization layer PLN that are successively stacked.

Along the direction pointing from the back side of the display panel to the front side thereof, the third pad region (i.e., a region in which the driver chip 2 is bonded) of the display panel includes the first substrate PI1, the first shielding layer Barrier1, the second substrate PI2, the light-shielding layer BSM, the second shielding layer Barrier2, the buffer layer Buffer1, the insulation layer GI1, the insulation layer GI2, the metal layer Gate2, the insulation layer ILD, the metal layer SD, and the planarization layer PLN that are successively stacked.

Along the direction pointing from the back side of the display panel to the front side thereof, the third pad region (i.e., a region in which the driver chip 2 is bonded) of the display panel includes the first substrate PI1, the first shielding layer Barrier1, the second substrate PI2, the light-shielding layer BSM, the second shielding layer Barrier2, the buffer layer Buffer1, the insulation layer GI1, the insulation layer GI2, the metal layer Gate2, the insulation layer ILD, the metal layer SD, and the planarization layer PLN that are successively stacked.

In some embodiments, the second shielding layer Barrier2 is a two-layer structure, and the light-shielding layer BSM is between the two layer structures of the second shielding layer Barrier2.

FIG. 5 is a structural diagram of a display device according to some embodiments of the present disclosure. By bending the display panel 1 of the display device illustrated in FIG. 3, the circuit board 3 is fixed to the back side of the display panel 1. A ferrite layer 4 is subsequently provided on a side, back to the display panel 1, of the circuit board 3, such that the magnetic flux of the near-field communication antenna is increased. A polarizer 5 is attached to the front side of the display panel 1, and a cover 7 is attached to the polarizer 5 by an optical adhesive 6, and thus the display device illustrated in FIG. 5 is acquired.

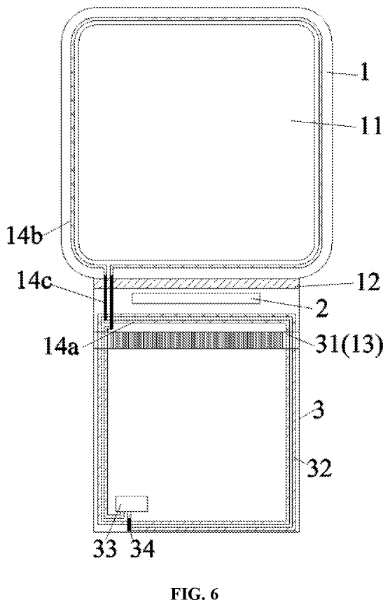

In some embodiments, referring to FIG. 6, the at least one first wiring 14 described above includes a first segment 14a traveling through the gap region described above and a second segment 14b surrounding the display region 11 of the display panel 2. The first segment 14a and the second segment 14b are disposed in the same layer and connected in series by a first jumper 14c. In the embodiments, the first segment 14a is disposed in the gap region as described above, and the second segment 14b is disposed in the non-bonding region.

In these embodiments, the second segment 14b approximately forms a turn of antenna coil, and the first segment 14a is connected to the second wiring 32 to form another turn of antenna coil. The near-field communication antenna makes full use of the wiring space in the display panel, which is conducive to increasing the number of turns of the near-field communication antenna and improving the performance of the near-field communication antenna.

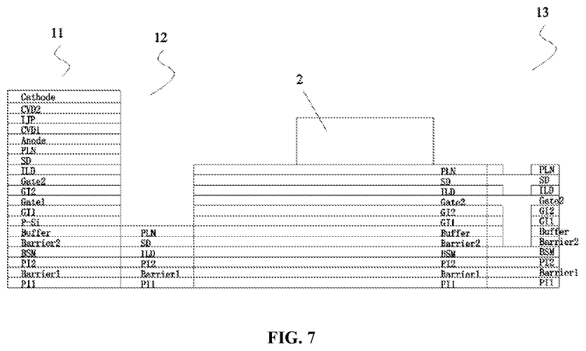

Specifically, FIG. 7 illustrates a layer structure of different regions of the display panel in the display device illustrated in FIG. 6. The difference between the layer structure illustrated in FIG. 7 and the layer structure illustrated in FIG. 4 lies in two points. The first one is that the display device illustrated in FIG. 7 does not have a layer structure associated with the touch function, and the second one is that the metal layer SD of the display panel in the display device illustrated in FIG. 7 serves as a wiring layer where the first jumper 14c is disposed.

In some embodiments, the display panel further includes a substrate, and a top-gate transistor and a light-shielding layer BSM that are disposed on the substrate. The light-shielding layer BSM is opposite to an active layer P—Si of the top-gate transistor and between the active layer P—Si and the substrate. The first segment 14a, the second segment 14b, and the light-shielding layer BSM are disposed in the same layer.

In some embodiments, referring to FIG. 7, the first substrate PI1, the first shielding layer Barrier1, and the second substrate PI2 form a substrate of a composite structure. A gate electrode of the top-gate transistor is provided, in some embodiments, in the metal layer Gate1, and a source-drain electrode thereof is provided, in some embodiments, in the metal layer SD.

Such an arrangement makes full use of the wiring layer in which the light-shielding layer BSM is disposed, and reduces an impact on the wiring related to the display function.

In some embodiments, at least two second wirings 32 are provided, each of which is at least partially disposed in a bottom wiring layer of the circuit board 3. The bottom wiring layer is a wiring layer of the circuit board 3 that is most proximal to the display panel 1. At least one of the second wirings 32 spans over other second wirings 32 by a second jumper 34. The circuit board 3 further includes a connector 33, which is disposed on an inner side of the antenna coil, and the lead end of the antenna coil is connected to the connector 33.

Referring to FIGS. 3 and 6, the circuit board 3 includes at least two layers of wirings and the connector 33. The connector 33 is disposed on an inner side of a wiring region where the at least two second wirings 32 are disposed. The at least one first wiring 14 and the at least two second wirings 32 are connected to form the antenna coil of multiple turns. A respective end of each of the two second wirings 32 is served as a lead end, and the lead end is connected to the connector 33. At least one of the second wirings 32 spans over other second wirings 32 by the second jumper 34. The at least two second wirings 32 are disposed in the same layer except for a segment in which the second jumper 34 is disposed.

A center region of the circuit board 3 is used for wiring the display (or touch) function, and a peripheral region of the circuit board 3 is used for wiring the near-field communication antenna, which avoids mutual interference between the two in terms of structural and electrical properties.

In some embodiments, referring to FIG. 3, the display panel 1 is a flexible panel. In the case that the display panel is in a flat state, the bendable region 12 of the display panel 1 is disposed on a side, distal from the first pad region, of the third pad region.

In conjunction with FIG. 5, in the case that the display panel 1 is bent, an orthographic projection of the near-field communication antenna in a plane where the display device is disposed is symmetrical with an orthographic projection of the near-field communication antenna in a plane where the display device is disposed before the display panel 1 is bent. The near-field communication antenna fully utilizes the wiring space of the display panel 1 and the wiring space of the circuit board 3, and an area enclosed by the near-field communication antenna is large enough, such that the performance of the antenna is improved.

In some embodiments, the circuit board 3 is provided with a plurality of wiring layers. In the case that the display panel 1 is in a bending state, the circuit board 3 is fixed to the back side of the display panel 1, the wiring layer, most proximal to the display panel 1, of the circuit board 3 is the bottom wiring layer of the circuit board 3, and the second wirings 32 are all disposed in the bottom wiring layer of the circuit board 1.

A portion, disposed on the circuit board 3, of the near-field communication antenna is more proximal to the display panel 1, i.e., more proximal to an external transceiver device, which is conducive to increasing the sensitivity of the antenna.

In some embodiments, in the case that the near-field communication antenna includes a turn of coil, the portion, disposed on the circuit board 1, of the near-field communication antenna is provided in the same wiring layer.

In some embodiments, referring to FIGS. 3 and 6, the circuit board 3 includes a plurality of wiring layers. In the case that the display panel 1 is in a bending state, the circuit board 3 is fixed to the back side of the display panel 1, the wiring layer, most proximal to the display panel 1, of the circuit board 3 is the bottom wiring layer of the circuit board 3, and at least one of the second wirings 32 spans over other second wirings 32 by the second jumper 34, wherein the at least two second wirings 32 are both disposed in the bottom wiring layer of the circuit board 3 except for the segment where the second jumper 34 is disposed.

In the portion, disposed on the circuit board 3, of the near-field communication antenna, most of the wirings are more proximal to the display panel 1, i.e., more proximal to the external transceiver device, which is conducive to increasing the sensitivity of the antenna.

In some embodiments, the display panel 1 includes a light-emitting diode display panel. The light-emitting diode display panel is, in some embodiments, an organic light-emitting diode (OLED) display panel or a micro light-emitting diode (Micro-LED or Mini-LED) display panel.

The present disclosure adopts the following technical solution: a display apparatus, including the display device described above. The display apparatus is any product or component having a display function. The display apparatus is, in some embodiments, a smart wearable device, a smartphone, a tablet computer, and the like.

Each embodiment in the present disclosure is described progressively, with identical and similar portions of each embodiment being referenced to each other, and each embodiment focuses on differences from other embodiments.

The scope of protection of the present disclosure is not limited to the embodiments described above. It is clear that those skilled in the art may make various changes and deformations to the present disclosure without departing from the scope and spirit of the present disclosure. To the extent that such modifications and deformations fall within the scope of the claims of the present disclosure and their technical equivalents, the present disclosure is intended to encompass such modifications and deformations as well.

1. A display device, comprising: a display panel and a circuit board, wherein the display panel comprises a display region and a non-display region; wherein
a first wiring is distributed in the non-display region;
a second wiring is distributed in the circuit board; and
the circuit board is bonded to the non-display region, and the second wiring is connected to the first wiring to form a near-field communication antenna.

2. The display device according to claim 1, wherein the non-display region comprises a non-bonding region surrounding the display region and a bonding region disposed at an edge, distal from the display region, of the non-bonding region, wherein the first wiring is disposed at least in the bonding region.

3. The display device according to claim 2, wherein
the bonding region comprises a first pad region provided with a plurality of first pads, wherein the first pad region is disposed at an edge, distal from the non-bonding region, of the bonding region, the first wiring is outside the first pad region, and at least one end of the first wiring is connected to the first pad;
the circuit board comprises a second pad region provided with a plurality of second pads, wherein the second pad region is disposed at an edge of the circuit board, the second wiring is outside the second pad region, and at least one end of the second wiring is connected to the second pad; and
the plurality of first pads are bonded to the plurality of second pads.

4. The display device according to claim 3, wherein the plurality of first pads are provided along an edge of the bonding region, and the first wiring is connected to an outermost first pad of the plurality of first pads.

5. The display device according to claim 3, wherein the plurality of second pads are provided along an edge of the circuit board, and the second wiring is connected to an outermost second pad of the plurality of second pads.

6. The display device according to claim 1, wherein the second wirings are provided along an edge of the circuit board.

7. The display device according to claim 3, further comprising: a driver chip, wherein the driver chip is bonded to the bonding region and between the first pad region and the non-bonding region, and at least one of the first wirings travels through a gap region between the first pad region and the driver chip.

8. The display device according to claim 7, wherein the first wirings are all disposed in a same layer and are all disposed in the gap region.

9. The display device according to claim 8, wherein the display panel further comprises a substrate, and a transistor and a light-shielding layer that are disposed on the substrate, wherein the light-shielding layer is opposite to an active layer of the transistor and between the active layer and the substrate, and the first wiring and the light-shielding layer are disposed in a same layer.

10. The display device according to claim 7, wherein at least one of the first wirings comprises a first segment and a second segment, wherein the first segment is disposed in the gap region, the second segment is disposed in the non-bonding region and surrounds the display region, and the first segment and the second segment are disposed in a same layer and connected to each other by a first jumper.

11. The display device according to claim 10, wherein the display panel further comprises a substrate, and a transistor and a light-shielding layer that are disposed on the substrate, wherein the light-shielding layer is opposite to an active layer of the transistor and between the active layer and the substrate, and the first segment and the second segment are disposed in a same layer as the light-shielding layer.

12. The display device according to claim 2, wherein the non-display region further comprises a bendable region, wherein the bendable region is disposed between the non-bonding region and the bonding region.

13. The display device according to claim 12, wherein the circuit board is disposed on a back side of the display panel, the circuit board is provided with a plurality of wiring layers, and the second wirings are all disposed in a bottom wiring layer of the circuit board, wherein the bottom wiring layer is a wiring layer, most proximal to the display panel, of the circuit board.

14. The display device according to claim 12, wherein the circuit board is disposed on a back side of the display panel, the circuit board is provided with a plurality of wiring layers, at least two second wirings are provided, and each of the second wirings is at least partially disposed in a bottom wiring layer of the circuit board, wherein the bottom wiring layer is a wiring layer, most proximal to the display panel, of the circuit board, and at least one of the second wirings spans over the other of the second wirings by a second jumper.

15. The display device according to claim 1, further comprising: a plurality of first wirings and a plurality of second wirings, wherein the plurality of first wirings and the plurality of second wirings are connected to form an antenna coil, and one end of one of the plurality of second wirings and one end of another of plurality of second wirings are lead ends of the antenna coil.

16. The display device according to claim 15, wherein the circuit board further comprises a connector, wherein the connector is disposed on an inner side of the antenna coil, and the lead end is connected to the connector.

17. The display device according to claim 16, wherein the circuit board comprises at least two layers of wirings, at least one of the two lead ends of the antenna coil extends to the inner side of the antenna coil by a second jumper, and portions of the second wirings, except for the second jumper, are disposed in a same layer.

18. The display device according to claim 1, wherein the display panel comprises a light-emitting diode display panel.

19. A display apparatus, comprising: a display device; wherein
the display device comprises: a display panel and a circuit board, wherein the display panel comprises a display region and a non-display region; wherein
a first wiring is distributed in the non-display region;
a second wiring is distributed in the circuit board; and
the circuit board is bonded to the non-display region, and the second wiring is connected to the first wiring to form a near-field communication antenna.

20. The display apparatus according to claim 19, wherein the non-display region comprises a non-bonding region surrounding the display region and a bonding region disposed at an edge, distal from the display region, of the non-bonding region, wherein the first wiring is disposed at least in the bonding region.
